(19) United States
(12) Patent Application Publication
(10) Pub. No.: US 2005/0007740 A1
(43) Pub. Date: Jan. 13, 2005

(54) Optimised application of pcms in chillers

(76) Inventors: Mark Neuschuetz, Darmstadt (DE); Natascha Lotz, Erzhausen (DE); Ralf Glausch, Muehltal (DE)

Correspondence Address: MILLEN, WHITE, ZELANO & BRANIGAN, P.C., 2200 CLARENDON BLVD., SUITE 1400, ARLINGTON, VA, 22201, US

(21) Appl. No.: 10/496,566

(22) PCT Filed: Sep. 27, 2002
(86) PCT No.: PCT/EP02/10865

(30) Foreign Application Priority Data
Nov. 24, 2001 (DE) 101 57 671.4

(51) Int. Cl. H05K 7/20

(52) U.S. Cl. 361/704

(57) ABSTRACT

The present invention relates to the use of phase change materials in devices for cooling, in particular, electrical and electronic components.

The present invention relates to the use of phase change materials in cooling devices.

In industrial processes, heat peaks or deficits often have to be avoided, i.e. temperature control must be provided. This is usually achieved using heat exchangers. In the simplest case, they may consist merely of a heat conduction plate, which dissipates the heat and releases it to the ambient air, or alternatively contain heat transfer media, which firstly transport the heat from one location or medium to another.

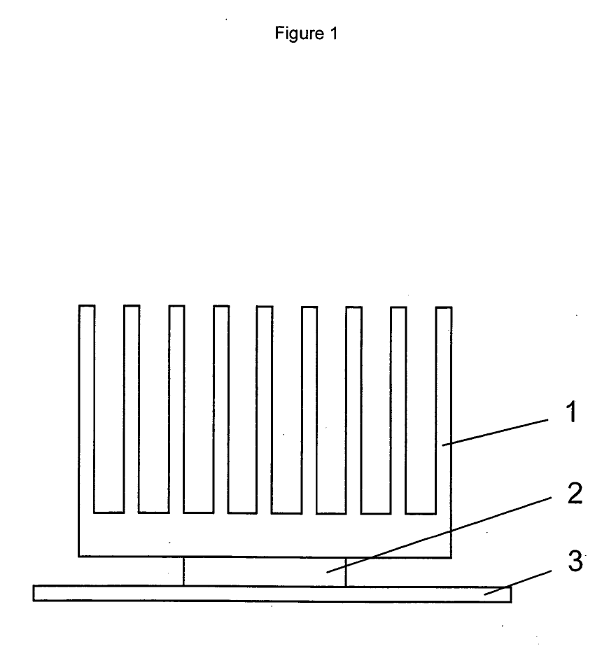

The state of the art (FIG. 1) for the cooling of electronic components, such as, for example, microprocessors (central processing units=CPUs) (2), are heat sinks made from extruded aluminium, which absorb the heat from the electronic component, which is mounted on support (3), and release it to the environment via cooling fins (1). The convection at the cooling fins is generally supported by fans.

Heat sinks of this type must always be designed for the most unfavourable case of high outside temperatures and full load of the component in order to avoid overheating, which would reduce the service life and reliability of the components. The maximum working temperature for CPUs is between 60 and 90° C., depending on the design.

As the clock speed of CPUs becomes ever faster, the amount of heat they emit jumps with each new generation. While hitherto peak output power levels of a maximum of 30 watts have had to be dissipated, it is expected that in the next 8 to 12 months cooling capacities of up to 90 watts will be necessary. These output power levels can no longer be dissipated using conventional cooling systems.

For extreme ambient conditions, as occur, for example, in remote-controlled missiles, heat sinks, in which the heat emitted by electronic components is absorbed in phase change materials, for example in the form of heat of melting, have been described (U.S. Pat. No. 4,673,030A, EP 116503A, U.S. Pat. No. 4,446,916A). These PCM heat sinks serve for short-term replacement of dissipation of the energy into the environment and cannot (and must not) be re-used.

Known storage media are, for example, water or stones/concrete for the storage of sensible heat or phase change materials (PCMs), such as salts, salt hydrates or mixtures thereof, or organic compounds (for example paraffin) for the storage of heat in the form of heat of melting (latent heat).

It is known that when a substance melts, i.e. is converted from the solid phase into the liquid phase, heat is consumed, i.e. absorbed, and is stored as latent heat so long as the substance remains in the liquid state, and that this latent heat is liberated again on solidification, i.e. on conversion from the liquid phase into the solid phase.

The charging of a heat storage system basically requires a higher temperature than can be obtained during discharging, since a temperature difference is necessary for the transport or flow of heat. The quality of the heat is dependent on the temperature at which it is available: the higher the temperature, the better the heat can be dissipated. For this reason, it is desirable for the temperature level during storage to drop as little as possible.

In the case of storage of sensible heat (for example by heating water), the input of heat is associated with constant heating of the storage material (and the opposite during discharging), while latent heat is only stored and discharged at the phase-transition temperature of the PCM. Latent heat storage therefore has the advantage over sensible heat storage that the temperature loss is restricted to the loss during heat transport from and to the storage system.

The storage media employed hitherto in latent heat storage systems are usually substances which have a solid-liquid phase transition in the temperature range which is essential for the use, i.e. substances which melt during use.

Thus, the literature discloses the use of paraffins as storage medium in latent heat storage systems. International patent application WO 93/15625 describes shoe soles which contain PCM-containing microcapsules. The application WO 93/24241 describes fabrics having a coating comprising microcapsules of this type and binders. The PCMs employed here are preferably paraffinic hydrocarbons having from 13 to 28 carbon atoms. European Patent EP-B-306 202 describes fibres having heat-storage properties in which the storage medium is a paraffinic hydrocarbon or a crystalline plastic, and the storage material is integrated into the basic fibre material in the form of microcapsules.

U.S. Pat. No. 5,728,316 recommends salt mixtures based on magnesium nitrate and lithium nitrate for the storage and utilisation of thermal energy. The heat storage here is carried out in the melt at above the melting point of 75° C.

In the said storage media in latent heat storage systems, a transition into the liquid state takes place during use. This is accompanied by problems in the case of industrial use of storage media in latent heat storage systems since sealing or encapsulation is always necessary in order to prevent leakage of liquid resulting in loss of substance or contamination of the environment. Especially in the case of use in or on flexible structures, such as, for example, fibres, fabrics or foams, this generally requires microencapsulation of the heat storage materials.

In addition, the vapour pressure of many potentially suitable compounds increases greatly during melting, and consequently the volatility of the melts often stands in the way of long-term use of the storage materials. On industrial use of melting PCMs, problems frequently arise due to considerable volume changes during melting of many substances.

A new area of phase change materials is therefore provided with a particular focus. These are solid-solid phase change materials. Since these substances remain solid over the entire temperature range of the application, there is no longer a requirement for encapsulation. Loss of the storage medium or contamination of the environment by the melt of the storage medium in latent heat storage systems can thus be excluded. This group of phase change materials is finding many new areas of application.

U.S. Pat. No. 5,831,831A, JP 10135381A and SU 570131A describe the use of PCM heat sinks which are similar to one another in non-military applications. A common feature of the inventions is the omission of conventional heat sinks (for example with cooling fins and fans).

The PCM heat sinks described above are not suitable for absorbing the peak output power of components having an irregular output power profile since they do not ensure optimised discharge of the PCM or also absorb the base load.

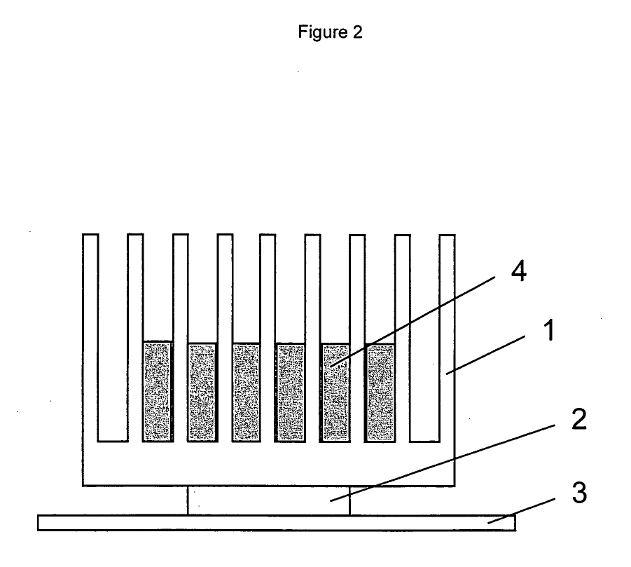

DE 100 27 803 (FIG. 2) proposes buffering the output power peaks of an electrical or electronic component with the aid of phase change materials (PCMs), the device for cooling heat-producing electrical and electronic components (2) having a non-uniform output power profile essentially consisting of a heat-conducting unit (1) and a heat-absorbing unit (4) containing a phase change material (PCM).

The object of the present invention is to cool heat-producing components more effectively and to even out temperature peaks.

This object is achieved by a device for cooling heat-producing components having a non-uniform output power profile, essentially consisting of a heat-dissipating unit (1) and a heat-absorbing unit (4) which contains at least one phase change material (PCM) in accordance with the main claim.

The invention is distinguished by the fact that the at least one PCM is arranged in the cooling device in such a way that its phase change temperature (T_{PC}) corresponds to the ambient temperature in the cooling device, which, in accordance with the temperature gradient, is at the heat-producing unit (2) temperature to be buffered.

The invention is preferably distinguished by the fact that it has at least two PCMs having different phase change temperatures (T_{PC}). The PCMs are arranged in such a way with respect to one another that the PCM having the higher T_{PC} is in each case located in the relatively warm region of the cooling device. The T_{PC} are in each case below the critical maximum temperature of the heat-producing component (2), at which overheating of this component would occur. The critical maximum temperature is the temperature of the heat-producing component which must not be exceeded.

The present invention relates, in particular, to devices for cooling electrical and electronic components which have a non-uniform output power profile, such as, for example, memory chips or microprocessors (MPUs=microprocessing units) in desktop or laptop computers or servers, both on the motherboard and on graphics cards, power supplies, hard disks and other electronic components which emit heat during operation.

Cooling of these types with the aid of PCMs to even out heat peaks are, however, not restricted to use in computers. The systems according to the invention can be used in all devices which have output power variations and in which heat peaks are to be evened out since overheating can cause possible defects to occur. Examples thereof, which do not restrict generality, are power circuits and power switching circuits for mobile communications, transmitter circuits for mobile telephones and fixed transmitters, control circuits for electromechanical actuating elements in industrial electronics and in motor vehicles, high-frequency circuits for satellite communications and radar applications, single-board computers and for actuating elements and control units for domestic appliances and industrial electronics. The cooling devices according to the invention may furthermore also be used, for example, in motors for elevators, sub-stations or internal-combustion engines.

Cooling devices according to the invention are, for example, heat sinks. Conventional heat sinks can be improved through the use of PCMs.

The heat flow from heat-producing component to heat sink should not be interrupted, i.e. the heat should flow firstly through the heat-dissipating unit, for example the heat sink, and not to the PCM. An interruption in this sense exists if the PCMs, owing to the design of the heat sink, firstly have to absorb the heat before the heat can be dissipated via the cooling fins—which results in an impairment of the performance of the heat sink for a given design.

In order to ensure that the PCMs only absorb the output power peaks, the PCMs are therefore preferably arranged in or on the cooling device in such a way that the classical cooling performance of the heat-dissipating unit is if at all possible not impaired and that a significant heat flow to the PCM only occurs if the heatdissipating unit exceeds the phase change temperature T_{PC} of the respective PCM. Before this point in time, only a small amount of heat flows into the PCM as is absorbed during normal temperature increases of the environment. If, however, T_{PC} is reached, further cooling takes place (i.e. dissipation of the heat) through the heat-dissipating unit and in addition an increased heat flow to the PCM occurs.

When the critical maximum temperature of the heat-producing component is reached, the cooling device according to the invention has a defined temperature gradient between the heat-producing unit and the opposite end of the heat-dissipating unit. It has been found that particularly suitable PCMs are those whose phase change temperatures T_{PC} are in a suitable manner below the critical maximum temperature for the heat-producing unit. The PCMs used in accordance with the invention are therefore preferably selected and arranged in the cooling device in such a way that their T_{PC} are matched as precisely as possible to this defined critical temperature gradient, i.e. the phase changes occur virtually at the same time as and/or just below this temperature gradient.

For example, in commercially available heat sinks with fans for CPUs of desktop computers, considerable temperature gradients occur, which can be from 20 to 40° C. from the CPU/heat sink interface to the opposite end of the cooling fins. Suitable T_{PC} for the PCM which is closest to the heat-producing unit are, for example in the case of microprocessors, from about 10 to 15° C. below the critical maximum temperature for the heat-producing component. The PCMs arranged more remotely have correspondingly lower T_{PC}. Owing to the temperature gradient in the cooling device, the different T_{PC} in the arrangement according to the invention having at least two PCMs are then preferably reached at approximately the same time, meaning that the rise in performance of the cooling device is significantly increased and a booster effect of the PCMs becomes evident.

Furthermore, the significant heat flow to the PCM should advantageously only commence at the highest possible temperatures. In this way, the cooling device according to the invention operates in a very substantially conventional manner virtually up to its critical maximum temperature gradient, thus ensuring a maximum classical cooling performance. Only when the T_{PC} is reached is the cooling performance supplemented by the heat absorption by the PCMs. This causes a sudden increase in the performance of the cooling device, and a booster effect of the PCMs becomes evident. This has the result that the heat-producing component is not overheated.

Through the use of PCM in the manner according to the invention, cooling devices of lower cooling performance can be used since the extreme heat peaks do not have to be dissipated, but instead are buffered.

Depending on the critical maximum temperature determined by the heat-producing component, all known PCMs are suitable for the device according to the invention.

Suitable for use of the PCMs are encapsulated materials, solid-solid PCMs, PCMs in matrices, solid-liquid PCMs in cavities or a mixture of the said forms. Suitable matrices for solid-solid or solid-liquid PCMs are in particular polymers, graphite, for example expanded graphite (for example Sigri λ from SGL), or porous inorganic substances, such as, for example, silica gel and zeolites. At least one PCM used in accordance with the invention is preferably a solid/solid PCM.

Various PCMs are available for the device according to the invention. It is in principle possible to use PCMs whose phase change temperature is between −100° C. and 150° C. For use in electrical and electronic components, PCMs in the range from ambient temperature to 95° C. are preferred. The materials here can be selected from the group consisting of paraffins (C₂₀-C₄₅), inorganic salts, salt hydrates and mixtures thereof, carboxylic acids or sugar alcohols. A non-restrictive selection is shown in Table 1.

TABLE 1

| | Melting point | Enthalpy | |
|---|---|---|---|
| Material | [° C.] | of melting [J/g] | Group |
| Heneicosane | 40 | 213 | Paraffins |
| Docosane | 44 | 252 | Paraffins |
| Tricosane | 48 | 234 | Paraffins |
| Sodium thiosulfate | 48 | 210 | Salt hydrates |
| pentahydrate | | | |
| Myristic acid | 52 | 190 | Carboxylic acids |
| Tetracosane | 53 | 255 | Paraffins |
| Hexacosane | 56 | 250 | Paraffins |
| Sodium acetate | 58 | 265 | Salt hydrates |
| trihydrate | | | |
| Nonacosane | 63 | 239 | Paraffins |
| Sodium hydroxide | 64 | 272 | Salt hydrates |
| monohydrate | | | |
| Stearic acid | 69 | 200 | Carboxylic acids |
| Mixture of lithium | 75 | 180 | Salt hydrates |
| nitrate, magnesium | | | |
| nitrate hexahydrate | | | |
| Trisodium | 75 | 216 | Salt hydrates |
| phosphate | | | |
| dodecahydrate | | | |
| Magnesium nitrate | 89 | 160 | Salt hydrates |
| hexahydrate | | | |
| Xylitol | 93-95 | 270 | Sugar alcohols |

Also suitable are, for example, solid-solid PCMs selected from the group consisting of di-n-alkylammonium salts, optionally with different alkyl groups, and mixtures thereof. Particularly suitable PCMs for use in electrical and electronic components are those whose T_{PC} is between the ambient temperature and 95° C., such as, for example, dihexylammonium bromide, dioctylammonium bromide, dioctylammonium chloride, dioctylammonium acetate, dioctylammonium nitrate, dioctylammonium formate, didecylammonium chloride, didecylammonium chlorate, didodecylammonium chlorate, didodecylammonium formate, didecylammonium bromide, didecylammonium nitrate, didecylammonium acetate, didodecylammonium acetate, didodecylammonium sulfate, didodecylammonium chloride, dibutylammonium 2-nitrobenzoate, didodecylammonium propionate, didecylammonium formate, didodecylammonium nitrate and didodecylammonium bromide.

In a preferred embodiment, the PCMs comprise at least one auxiliary in addition to the actual heat storage material. The heat storage material and the at least one auxiliary are in the form of a mixture, preferably in the form of an intimate mixture.

The auxiliary is preferably a substance or preparation having good thermal conductivity, in particular a metal powder or metal granules (for example aluminium or copper) or graphite. These auxiliaries ensure good heat transfer.

In a further preferred embodiment, the at least one auxiliary present in the PCM in addition to the actual heat storage material can be a binder, in particular a polymeric binder. In this case, the particles of the heat storage material are preferably in finely divided form in the binder. Binders of this type are employed, in particular, if the PCM is to be held in shape. In addition, the binder establishes intimate contact on use, i.e. good wetting, between the heat storage medium and the surface of the heat-dissipating unit. For example, latent heat storage systems can be installed with an accurate fit for cooling electronic components. The binder expels air at the contact surfaces, thus ensuring close contact between heat storage material and component. Media of this type are therefore preferably used in devices for cooling electronic components.

A polymeric binder according to the invention can be any polymer which is suitable as binder in accordance with the application. The polymeric binder here is preferably a curable polymer or polymer precursor, in particular selected from the group consisting of polyurethanes, nitrile rubber, chloroprene, polyvinyl chloride, silicones, ethylene-vinyl acetate copolymers and polyacrylates. The polymeric binder used is particularly preferably silicone. Suitable methods for incorporation of the heat storage materials into these polymeric binders are well known to the person skilled in the art in this area. He has no difficulties in finding, where appropriate, the requisite additives which stabilise a mixture of this type.

For inorganic liquid-solid PCMs, nucleating agents, such as, for example, borax or various metal oxides, are preferably employed in addition.

The entire material, i.e. the PCM and, where appropriate, the auxiliaries, is preferably either in the form of a loose bed or in the form of a moulding. The term mouldings here is taken to mean, in particular, all structures which can be produced by compaction methods, such as, for example, pelleting, tabletting, roll compaction or extrusion. The mouldings here can adopt a very wide variety of spatial effects, such as, for example, spherical, cubic or cuboid shapes.

For moulding, the PCM can be pressed in pure form, pressed after comminution (for example grinding) or pressed in mixtures with the auxiliaries. The mouldings can be stored, transported and employed in a variety of ways without problems. For example, the mouldings can be inserted directly into electronic components. The mouldings are installed between the cooling fins in such a way that they are in intimate contact with the surfaces of the cooling fins. The thickness of the mouldings is selected in such a way that a frictional connection is formed between the fins and the moulding. The mouldings can also be inserted between cooling fins/heat exchangers before the latter are connected to form a stack.

Preference is furthermore given to cooling devices according to the invention whose heat-dissipating unit (1) has structures which increase the surface area. The heat-dissipating unit (1) particularly preferably has cooling fins. Structures of this type have a positive effect on the conventional cooling performance, making the cooling performance of the device according to the invention more effective in overall terms. The heat-dissipating unit (1) preferably furthermore has a fan on the side opposite the heat-producing unit (2) in order to support the cooling performance.

The present invention furthermore relates to a component (Z) which essentially consists of a cooling device according to the invention and a heat-producing unit (2). The heat-dissipating and heat-absorbing units (1) and (4) and the unit (2) are arranged in relation to one another in such a way that the heat flow between the heat-producing component (2) and the heat-dissipating unit (1) takes place in direct contact.

The heat-producing unit (2) is preferably an electrical or electronic component, particularly preferably an MPU (microprocessing unit), in particular a CPU (central processing unit), or a memory chip of a computer.

The device according to the invention is explained in greater detail below with reference to a general example of the cooling of CPUs for computers.

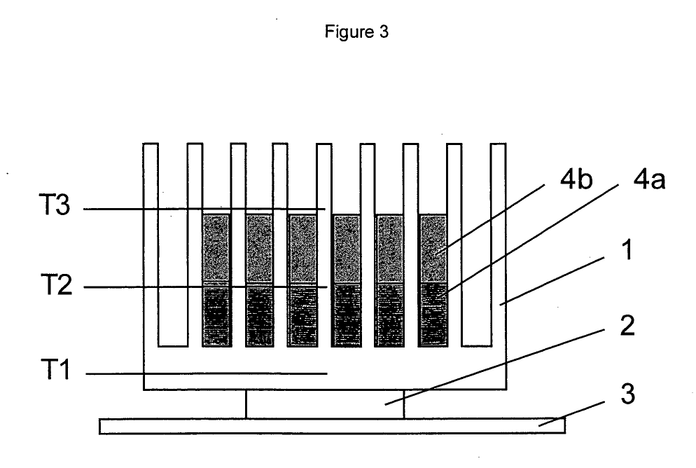

In a device according to the invention (FIG. 3), the PCMs (4a+4b) are arranged in or on the heat sink (1) in such a way that the heat flows firstly through the heat sink and subsequently through the PCMs i.e. a significant heat flow from the CPU (2) on the support (3) to the PCMs (4a, 4b) only takes place when the corresponding heat-sink regions have exceeded the phase change temperature T_{PC} of the adjacent PCM. In this way, it is ensured that the PCMs only absorb output power peaks. In high-power computers, temperatures of 60-90° C. (T1) are reached at the foot of the heat sink. The cooling fins have a significant temperature gradient, with the temperature in the region (T3) further away from the CPU being below that in the vicinity of the CPU (T2). Owing to high-performance fans at the opposite end, they only reach temperatures of T3=40-50° C. and T2=50-70° C. here.

If the phase change temperature of PCM1 (4a) is passed through to the temperature which exists in the vicinity of the CPU (T2ₘₐₓ) in accordance with the temperature gradient at the critical maximum temperature of the CPU in the heat sink, and the phase change temperature of PCM2 (4b) is correspondingly passed through in the more remote region of the heat sink (T3ₘₐₓ), the phase change of the two materials takes place virtually simultaneously and on reaching or just below the critical maximum temperature of the CPU (T1ₘₐₓ), i.e. the supporting action of the PCMs commences particularly efficiently. The later the heat storage action of the PCMs commences, i.e. the higher the heat-sink temperature can be, the greater the conventional and thus also the overall cooling performance of the device according to the invention.

The discharge of the PCM is likewise more efficient in this way, since the entire phase change material is discharged virtually simultaneously during cooling of the heat sink. A greater conventional cooling performance here results in faster discharge of the PCMs.

TABLE 2
Explanation of the designations in the figures

| Designation | Explanation |
|---|---|
| 1 | Cooling fins |
| 2 | Central processing unit (CPU) |
| 3 | Support |
| 4, 4a, 4b | Phase change material or materials (PCM) |
| Z | Entire component |
| T1 | Temperature in the vicinity of the CPU |
| T2 | Temperature of the cooling fins in the |
| | central region |
| T3 | Temperature of the cooling fins in the |
| | region further away from the CPU |

### EXAMPLE

For a processor with a maximum output power of 90 W, a heat sink as shown in FIG. 3 which has a cooling performance of 0.61 K/W at an ambient temperature of 30° C. is designed. Starting from a maximum operating temperature T1ₘₐₓ of 85° C., the temperatures in the centre and in the upper part of the cooling fins are T2ₘₐₓ 65° C. and T3ₘₐₓ 45° C. The phase change materials used are didodecylammonium chloride (PCM1), having a T_{PC} of 65° C., and didecylammonium chloride (PCM2), having a T_{PC} of 49° C.

With suitable PCMs, the heat sinks can be matched more precisely to the temperature gradient through the use of more than two PCMs.

1. Device for cooling heat-producing components, essentially consisting of a heat-dissipating unit (1) and a heat-absorbing unit (4) which contains at least one phase change material (PCM) having a phase change temperature (T_{PC}), where the PCM is arranged in the cooling device in accordance with its T_{PC} according to the temperature gradient.

2. Device according to claim 1, characterised in that the heat-absorbing unit (4) contains at least two PCMs having different T_{PC}, where the PCMs are arranged relative to one another in the cooling device in accordance with their T_{PC} according to the temperature gradient.

3. Device according to claim 1, characterised in that the T_{PC} are in each case below the critical maximum temperature of the heat-producing component (2).

4. Device according to claim 1, characterised in that the PCMs are arranged in such a way that their phase changes take place virtually at the same time and/or just below the temperature which, in accordance with the temperature gradient in the cooling device, corresponds to the critical maximum temperature of the heat-producing component (2).

5. Device according to claim 1, characterised in that the PCMs are arranged in such a way that the heat flow from the heat-producing component to the heat-dissipating unit (1) is not interrupted and a significant heat flow to the PCM only takes place when the temperature of the heat-dissipating unit (1) exceeds the phase change temperature T_{PC} of the PCM.

6. Device according to claim 1, characterised in that the PCM-containing unit (4) consists of one or more cavities into which the PCMs have been introduced, the cavities being located in the heat-dissipating unit (1).

7. Device according to claim 1, characterised in that at least one PCM is a solid/solid PCM.

8. Device according to claim 1, characterised in that at least one PCM is encapsulated.

9. Device according to claim 1, characterised in that at least one PCM is provided with one or more auxiliaries.

10. Device according to claim 9, characterised in that the auxiliary is a substance having good thermal conductivity, in particular a metal powder, metal granules or graphite, and/or a binder, in particular a polymeric binder.

11. Device according to claim 1, characterised in that the PCM and, where used, the auxiliaries, are in pressed form.

12. Device according to claim 1, characterised in that the heat-dissipating unit (1) has structures, in particular cooling fins, which increase the surface area.

13. Device according to claim 1, characterised in that the heat-dissipating unit (1) has a fan for additional cooling.

14. Component (Z) essentially consisting of a cooling device according to claim 1 and a heat-producing component (2), where the two structural units (1) and (4) and the component (2) are arranged in relation to one another in such a way that the heat flow between the heat-producing component (2) and the heat-dissipating unit (1) takes place in direct contact.

15. Component (Z) according to claim 14, characterised in that the component (2) is an electrical or electronic component, in particular an MPU (microprocessing unit) or a memory chip of a computer.

16. Computer containing a component according to claim 14.

17. Use of a device according to claim 1 or of a component characterised in that the heat-dissipating unit (1) has structures, in particular cooling fins which increase the surface area in computers and electronic data processing systems.

18. Use of a device according to claim 13 or of a component according to claim 14 or 15 in power circuits and power switching circuits for mobile communications, transmitter circuits for mobile telephones and fixed transmitters, control circuits for electromechanical actuating elements in industrial electronics and in motor vehicles, high-frequency circuits for satellite communications and radar applications, single-board computers and for actuating elements and control units for domestic appliances and industrial electronics.
